(19) United States
(12) Patent Application Publication
(10) Pub. No.: US 2015/0364300 A1
(43) Pub. Date: Dec. 17, 2015

(54) DETERMINING PRESENCE OF CONDUCTIVE FILM ON DIELECTRIC SURFACE OF REACTION CHAMBER

(71) Applicant: Lam Research Corporation, Fremont, CA (US)

(72) Inventor: Federico Galli, Los Gatos, CA (US)

(21) Appl. No.: 14/305,967

(22) Filed: Jun. 16, 2014

(51) Int. Cl. H01J 37/32; C23C 16/52

(52) U.S. Cl. CPC H01J 37/32935; H01J 37/3211; C23C 16/52; H01J 37/321; H01J 37/32862; H01J 2237/3321; H01J 2237/334; H01J 2237/3341; H01J 2237/335

(57) ABSTRACT

In one aspect, a plasma system includes a dielectric enclosure enclosing a portion of a reaction chamber, a conductive coil extending along a perimeter of the enclosure, and a generator for providing a first electrical signal to the coil to cause a plasma to be generated in the reaction chamber. The system additionally includes a probe located within the reaction chamber, a sensing device for sensing a second electrical signal generated in the probe via the plasma while the first electrical signal is provided to the coil, and a processing unit for determining a metric based on the sensed second electrical signal, the metric indicating a measure of deposition or removal of a conductive material on an inside surface of the enclosure.

### FIELD OF THE INVENTION

The present disclosure relates generally to plasma systems and processes, and more specifically, to systems and processes for determining a presence of a conductive film on an enclosure of a reaction chamber of a plasma system.

### BACKGROUND

Inductively-coupled plasma (ICP) systems can be used in a variety of microfabrication processes including substrate cleaning processes, surface conditioning processes, thin-film deposition processes, etching processes, and cleaning processes, among other applications. In an ICP system, a generator supplies a radio frequency (RF) electrical supply signal to an induction coil of the ICP system. While traversing the induction coil, the supply signal generates time-varying electromagnetic fields around the induction coil that generate time-varying electric currents through a process gas by way of electromagnetic induction. These electric currents, and associated voltages, supply the electric fields and energy to generate the plasma from the process gas.

### SUMMARY

In one aspect of the subject matter described in this disclosure, a system is described that includes a plasma source system. The plasma system includes a dielectric enclosure enclosing a portion of a reaction chamber, a conductive coil extending along a perimeter of the enclosure, and a generator for providing a first electrical signal to the coil to cause a plasma to be generated in the reaction chamber. The system additionally includes a probe located within the reaction chamber, the probe being electrically insulated from electrical ground at least while the first electrical signal is provided to the coil. The system additionally includes a sensing device for sensing a second electrical signal generated in the probe via the plasma while the first electrical signal is provided to the coil. The system further includes one or more processing units for determining a metric based on the sensed second electrical signal, the metric indicating a measure of deposition or removal of a conductive material on an inside surface of the enclosure.

In some implementations, the plasma system is an inductively-coupled plasma system and the first and the second electrical signals are radio frequency (RF) signals. In some implementations, one or more of the processing units include hardware or software for removing components of the sensed second electrical signal that have frequencies different than the frequency of the first electrical signal. In some implementations, the metric is a voltage amplitude of the filtered second electric signal.

In some implementations, the plasma is used to process a substrate, the process resulting in a deposition of the conductive material on the inside surface of the enclosure. In some such implementations, one or more of the processing units are further for determining whether a value of the metric has reached a threshold value, the threshold value indicating that the deposition of the conductive material on the inside surface of the enclosure has reached a predetermined measure. In some such implementations, when it is determined that the value of the metric has reached the threshold value, the processing units are further for outputting an indication to clean the enclosure or initiating a cleaning process to clean the enclosure. In some of the above implementations, the process is used to deposit or form a WFₓ species on or below a conductive surface of the substrate. In some other implementations, the process is used to deposit a conductive material on the substrate.

In some other implementations, the plasma is used in a cleaning process to remove conductive material previously deposited on the inside surface of the enclosure. In some such implementations, one or more of the processing units are further for determining whether a value of the metric over a time period has become substantially steady state, the steady state indicating that the removal of the conductive material on the inside surface of the enclosure has been substantially completed. In some such implementations, when it is determined that the value of the metric has become substantially steady state, the processing units are further for outputting an indication that the cleaning process is complete or initiating an end to the cleaning process.

In some implementations, the plasma system further includes a conductive platform (for example, a pedestal) for supporting the substrate in the reaction chamber. In some such implementations, the platform functions as or includes the probe.

In another aspect, a method includes supplying, by a first generator, a first electrical signal to a coil of a plasma system to cause a plasma to be generated in a reaction chamber of the plasma system, the reaction chamber being at least partially enclosed by a dielectric enclosure. The method additionally includes sensing, by a sensing device, an electrical characteristic of a second electrical signal generated in a probe via the plasma while the first electrical signal is provided to the coil, the probe being arranged within the reaction chamber. The method further includes determining a metric based on the electrical characteristic, the metric indicating a measure of deposition or removal of a conductive material on an inside surface of the enclosure.

In some implementations, the plasma system is an inductively-coupled plasma system and the first and the second electrical signals are radio frequency (RF) signals. In some implementations, the method further includes removing, from the sensed second electrical signal, components of the sensed second electrical signal that have frequencies different than the frequency of the first electrical signal. In some implementations, the metric is a voltage amplitude of the filtered second electric signal.

In some implementations, the plasma is used to process a substrate, the process resulting in a deposition of the conductive material on the inside surface of the enclosure. In some such implementations, the method further includes determining whether a value of the metric has reached a threshold value, the threshold value indicating that the deposition of the conductive material on the inside surface of the enclosure has reached a predetermined measure. In some such implementations, when it is determined that the value of the metric has reached the threshold value, the method further includes outputting an indication to clean the enclosure or initiating a cleaning process to clean the enclosure. In some of the above implementations, the process is used to deposit or form a WFₓ species on or below a conductive surface of the substrate. In some other implementations, the process is used to deposit a conductive material on the substrate.

In some other implementations, the plasma is used in a cleaning process to remove conductive material deposited on the inside surface of the enclosure. In some such implementations, the method further includes determining whether a value of the metric over a time period has become substantially steady state, the steady state indicating that the removal of the conductive material on the inside surface of the enclosure has been substantially completed. In some such implementations, when it is determined that the value of the metric has become substantially steady state, the method further includes outputting an indication that the cleaning process is complete or initiating an end to the cleaning process.

These and other aspects are described further below with reference to the drawings.

### BRIEF DESCRIPTION OF THE DRAWINGS

FIG. 1 shows a schematic depiction of an example inductively-coupled plasma (ICP) system suitable for use in conjunction with various implementations.

FIG. 2 shows a block diagram of example components of the example ICP system of FIG. 1.

FIG. 3 shows a flowchart illustrating an example process for determining a measure of deposition of a conductive material on an inside surface of an enclosure of a reaction chamber of a plasma system.

FIG. 4 shows a flowchart illustrating an example process for determining when or whether a concurrently running cleaning process has completed the removal of an accumulation of conductive material on an inside surface of an enclosure of a reaction chamber of a plasma system.

### DETAILED DESCRIPTION

In the following description, numerous specific details and examples are set forth in order to provide context and aid in the understanding of the disclosed implementations. The disclosed implementations may be practiced without some or all of these specific details. In some instances, well-known process steps or operations have not been described in detail to not unnecessarily obscure the disclosed implementations. While the disclosed implementations will be described in conjunction with the specific implementations and the drawings, it will be understood that the disclosed implementations are not limited to these specific implementations. Additionally, the conjunction “or” is intended herein in the inclusive sense where appropriate unless otherwise indicated; that is, the phrase “A, B or C” is intended to include the possibilities of “A,” “B,” “C,” “A and B,” “B and C,” “A and C” and “A, B and C.”

Various implementations described and referenced herein are directed generally to systems and processes for determining a presence of a conductive film on an enclosure of a reaction chamber of a plasma system. Some implementations more specifically relate to a process for determining an amount of accumulation of a conductive film on an enclosure of a reaction chamber of an inductively-coupled plasma (ICP) system. In some such implementations, the process for determining the accumulation of the conductive film is performed concurrently with a plasma-facilitated process for treating a substrate in the reaction chamber of the ICP system. Some other implementations more specifically relate to a process for determining when or whether an accumulation of a conductive film on an enclosure of a reaction chamber of an ICP system is removed. In some such implementations, the process for determining when or whether the conductive film is removed is performed concurrently with a plasma-facilitated process for cleaning the enclosure of the reaction chamber of the ICP system.

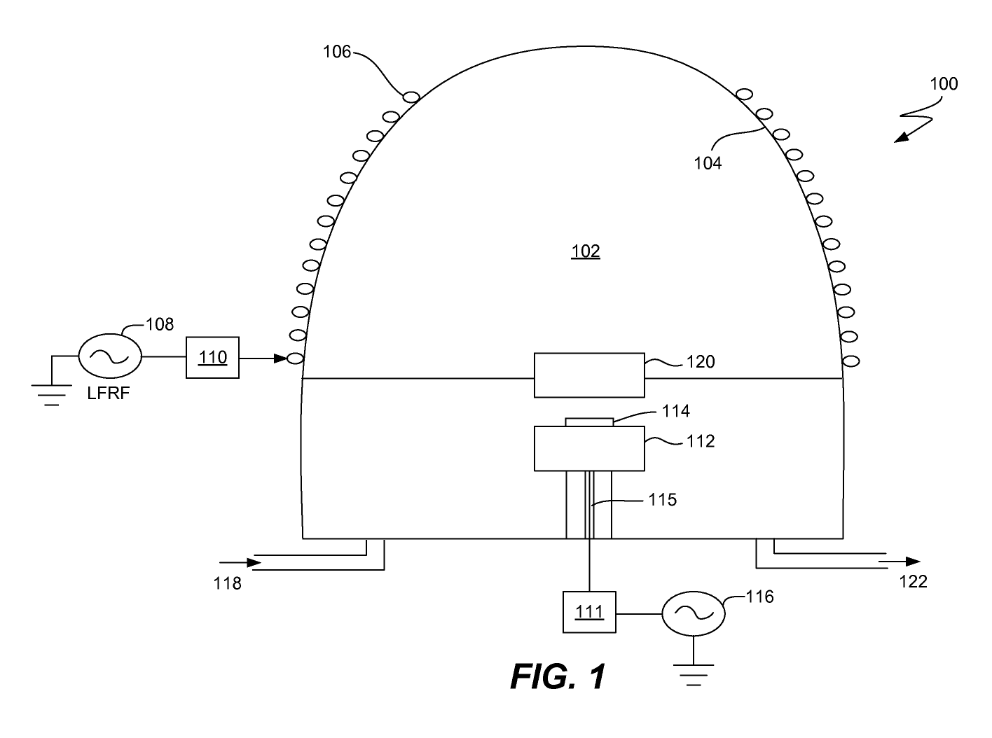

An ICP system can be used in a variety of semiconductor device fabrication and other microfabrication processes including substrate cleaning processes, metal cleaning processes, surface conditioning processes, thin-film deposition (e.g. plasma enhanced chemical vapor deposition) processes, etching (e.g., reactive-ion etching) processes, and chamber cleaning processes, among other applications. For example, an ICP system-generated plasma can be used to clean a substrate prior to deposition of a tungsten layer or to remove metal oxide from metal contacts prior to deposition of additional layers. FIG. 1 shows a cross-sectional side view of a schematic depiction of an example ICP system 100 suitable for use in conjunction with various implementations. The ICP system 100 includes a reaction chamber 102 (also referred to herein as a “plasma chamber”) in which the plasma is generated and in which the fabrication, cleaning, or other plasma-enhanced or plasma-facilitated processes are performed. In various implementations, the reaction chamber 102 is surrounded by an enclosure 104, such as, for example, in the shape of a hemispheric dome. The enclosure 104 is formed of a dielectric material such as, for example, aluminum oxide (Al₂O₃). An induction coil 106 (also referred to herein as a “coil”) is arranged along a perimeter of the enclosure. For example, the induction coil 106 can be arranged in a plurality of windings around the outside surface of the enclosure 104. The induction coil can be formed of copper or another highly conductive material.

A generator 108 supplies the power for the induction coil 106. In some implementations, the generator 108 is a medium frequency RF (MFRF) generator. The medium frequency range generally refers to radio frequencies in the range of 300 kilo-Hertz (kHz) to 1 Mega-Hertz (MHz). During operation, the generator 108 generates an RF alternating current (AC) supply signal that is supplied to the induction coil 106. In some specific applications, the generator 108 is configured to generate a supply signal having a frequency in the range of approximately 330 kHz to approximately 460 kHz. The generator 108 delivers the supply signal to the induction coil 106 via an impedance matching network 110.

Within the reaction chamber 102, a pedestal 112 can support a substrate 114 to be processed. For example, the substrate 114 can be a semiconductor (for example, silicon (Si)) wafer or a glass or other substrate material. The pedestal 112 can in some implementations include a chuck (also referred to herein as a “clamp” or “platform”) to hold the substrate 114 in place during processing, although in other implementations, a chuck may not be included. Where a chuck is included, the chuck may be an electrostatic chuck, a mechanical chuck or various other types of chuck suitable for use in the industry or research. In some implementations, the ICP system 100 also includes a heat transfer subsystem for supplying heat transfer to control the temperature of substrate 114 for various processes. For example, the heat transfer subsystem can control heat transfer to or from the pedestal 112 via a line within a lumen 115 in the base of the pedestal. In other implementations, the ICP system 100 may not include a heat transfer subsystem.

In some implementations, the ICP system 100 additionally includes a high frequency RF (HFRF) generator 116. For example, the HFRF generator 116 can provide a HFRF electrical signal to the pedestal 112 to electrically bias the substrate 114 during processing, for example, through a conducting line or electrode within the lumen 115. Additionally, the HFRF generator 116 can be used to draw charged species to the substrate 114 during one or more process steps. Electrical energy from the HFRF generator 116 can be supplied to the substrate 114 via an electrode of the pedestal 112 through capacitive coupling, for example. In some other implementations, the generator 116 can be configured to supply a bias in another frequency range less than or greater than RF frequencies. In some other implementations, the generator 116 can be configured to supply a DC bias. In the illustrated implementation, the generator 116 delivers the electrical signal to the pedestal 112 via an impedance matching network 111.

During operation, one or more process gases, such as argon (Ar), hydrogen (H₂), or nitrogen (N₂), among other examples, are introduced via one or more inlets 118. It is the process gas or gases that are partially ionized and dissociated into ions and radicals by the ICP system 100. In some applications, the process gases can be pre-mixed prior to input into the reaction chamber 102. In some implementations, the process gases can be introduced through a gas supply inlet mechanism including one or more orifices. Some of the orifices can orient the process gas or gases along a direction of injection intersecting an exposed surface of the substrate 114. In some other implementations, the gas or gas mixtures can be introduced from a primary gas ring 120. In various applications, the gas ring 120 can direct the gas toward the surface of the substrate 114. For example, injectors can be connected to the primary gas ring 120 to direct at least some of the gas or gas mixtures into the reaction chamber 102 and toward the substrate 114. Process gases exit the reaction chamber 102 via an outlet 122. A vacuum pump (for example, a turbomolecular pump) is typically used to draw the process gases out and to maintain a suitably low pressure within the reaction chamber 102.

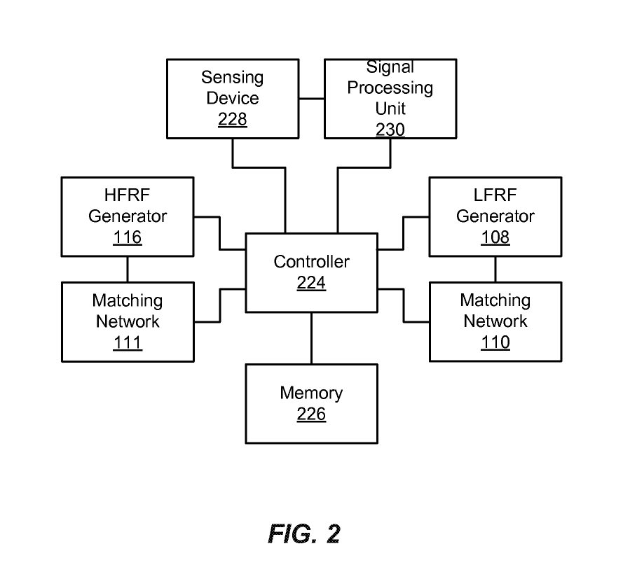

FIG. 2 shows a block diagram of example components of the example ICP system 100 of FIG. 1. The ICP system 100 includes, is integrated with, or is in communication with a system controller 224 that includes software or other computer-readable instructions for controlling process operations in accordance with the various implementations. For example, the controller 224 can control one or more of the hardware components of the ICP system 100 shown in FIG. 1. Specifically, the controller 224 can enable automated or user control of the LFRF generator 108, the HFRF generator 116, the matching networks 110 and 111, and other components of the ICP system 100. In some implementations, the controller 224 includes or is in communication with one or more memory devices 226 storing the software or other computer-readable instructions. The controller 224 also includes one or more processors (also referred to herein as “processing units”) configured to execute the computer-readable instructions it retrieves from the memory devices 226 so that the hardware—such as the generator 108, matching network 110, and other components of the ICP system 200—will perform the processes described herein.

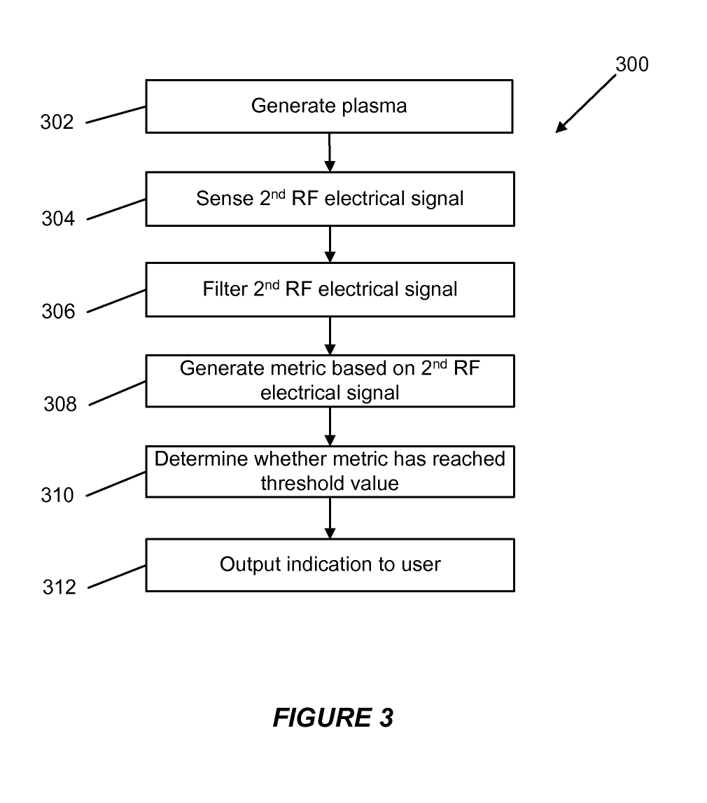

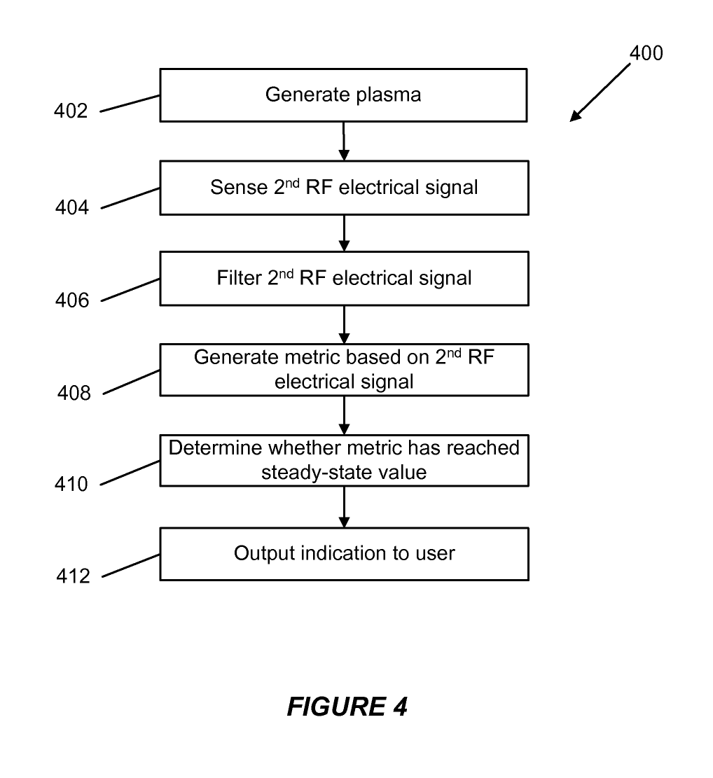

In some example implementations, the systems and processes described herein, including the ICP system 100 and the processes 300 and 400 described with reference to FIGS. 3 and 4, can be used in conjunction with the processing of a substrate, such as a semiconductor wafer or other substrate, using various lithographic patterning, deposition or treatment tools or processes. Such processes can be part of a grander process for the fabrication or manufacture of integrated circuit (IC) devices, other semiconductor devices, displays, LEDs, photovoltaic panels and the like. For example, the devices can include memory chips, processing units, analog or digital circuits or other electrical devices or components. In some implementations, the ICP system 100 can be an integrated part of a larger system or a separate system within a group of systems each for performing one or more processes in the processing of wafers. For example, the ICP system 100 can be part of a larger chemical vapor deposition (CVD) system.

Each IC or other device referenced above generally includes a multitude of electrical circuits or components such as, for example, transistors, interconnects, and packaging components, among other examples. Such components can be produced using various patterning techniques by etching or otherwise forming various features in or on the surface of a semiconductor wafer or other substrate (or a film deposited on the surface). Lithographic patterning typically includes some or all of the following steps, each step enabled with one or more processes, tools or systems: (1) application of photoresist on a substrate using a spin-on or spray-on tool; (2) curing of the photoresist using a hot plate or furnace or ultraviolet (UV) curing tool; (3) exposing the photoresist to visible, UV or X-ray light with a tool such as a wafer stepper; (4) patterning the exposed resist by developing the resist so as to selectively remove portions of the resist using a tool such as a wet bench; (5) transferring the resist pattern into an underlying film or substrate by using a dry or plasma-assisted etching tool; and (6) removing the resist using a tool such as an RF or microwave plasma resist stripper.

Such a feature as can be produced, treated or otherwise processed by the ICP system 100 can be used, for example, in the subsequent formation of an electrical via for a contact of a circuit component such as a transistor, capacitor, inductor, or memory storage cell. In various applications, after features are formed, a deposition process (for example, using a thermal CVD process) is used to deposit a conductive material in or on the features. For example, some features are subsequently coated with conformal conductive thin films. Some other features can be filled with conductive material. In some example applications, the ICP source system 100 is used to deposit a conductive metal, conductive metal alloy or other conductive material, such as tungsten (W), over various features to form conductive elements such as contacts, vias, and plugs. The features used to form the conductive elements are typically small (for example, on the microscale or nanoscale), relatively narrow, and include relatively small amounts of metal. As semiconductor manufacturers move to smaller technology nodes, metal deposition (or metallization) processes face significant scaling and integration challenges, such as minimizing resistance in conductive elements to meet the lower power consumption and high speed requirements of increasingly advanced devices. The resistance of the conductive elements, such as contacts, vias and plugs, can be reduced by, for example, ensuring that the respective features are completely filled with conductive material (for example, tungsten).

At nanoscale or microscale dimensions, even slight imperfections in the conductive elements can impact the resulting device's performance or cause a device to fail. For example, the filling of nanoscale features with conductive material using conventional CVD processes and techniques has been limited by the growing overhangs of the deposited conductive material at the openings of the features. The growing overhangs can eventually result in complete closures of the respective feature openings before lower portions of the features have been completely filled. Such voids in the resulting conductive elements can cause the conductive elements to have higher resistance and may eventually result in damage to the conductive elements rendering them ineffective or incapable of serving their intended purposes as designed.

To avoid the formation of overhangs around feature openings, in various implementations or applications, a deposition process proceeds in a number of iterations of deposition and treatment steps. Specifically, each deposition step (except in some instances the last deposition step) may be followed by a treatment step. In one specific example application, the ICP source system 100 performs each treatment step by forming and maintaining a plasma that breaks down nitrogen triflouride (NF₃) gas introduced into the reaction chamber 102 into nitrogen and fluorine ions. The fluorine radicals are the active treatment agents that bind with tungsten atoms at or near the surface of the tungsten material deposited in an earlier deposition step or steps in and around the opening of the feature to form, for example, WFₓ species (for example, WF₆). These species inhibit or delay subsequent deposition of the tungsten material in and around the opening of the feature. In some implementations, such fluorine radicals also are used as active etching agents to etch the opening of the feature allowing for the next deposition step to reach the bottom regions of the feature. In some other implementations, the etching step is replaced by a plasma treatment step localized to the feature opening. In some implementations or applications, the controller 220 may perform a predetermined number of iterations of deposition and treatment steps. In some instances, a minimum of two deposition steps and one intermediate treatment step are performed, while in some other instances, several deposition steps and several intermediate treatment steps are performed depending on, for example, the depth, complexity or other geometrical characteristic of the feature. In some other instances, a relative measurement of the thickness of the deposited tungsten is measured (for example, by means of optical end point detection methods) and provided to the controller 220, which then determines whether the deposition of the tungsten is complete. For example, the controller 220 may compare the estimated thickness with a target thickness to make the determination.

Because each treatment step makes use of plasma to deposit or form the WFₓ or other species, the treatment step can result in deposition of the tungsten (or other conductive material) on an inside surface (adjacent the reaction chamber 102) of the enclosure 104. For example, the plasma used in the treatment step can result in the sputtering of some of the tungsten previously deposited over the process wafer, some of which sputtered tungsten particles become deposited on the inner surface of the enclosure 104. This undesired deposition can, in some instances, be accelerated or made worse by an HFRF electrical signal supplied to the pedestal 112 by the HFRF generator 116. For example, as described above, the HFRF electrical signal supplied by the HFRF generator 116 can be used to bias the wafer to modulate the plasma to adjust the depth of the treatment step or the formation of the WF₆ or other species.

Conventional techniques and systems do not include a way to determine an amount, thickness or distribution of the accumulated tungsten or other conductive thin film inadvertently deposited on the inside surface of the enclosure 104. The enclosures of many ICP systems are typically not visible to the human eye. Instead, in many conventional systems and processes, the inside surface of the enclosure is cleaned after a predetermined number of wafers are processed (for example, the number could be based on the number of treatment steps required for each wafer). Additionally, in many conventional systems and processes, there is no way to determine when the cleaning process is complete; that is, when the tungsten or other conductive thin film is removed, or substantially removed, from the inner surface of the ICP system enclosure. In some conventional systems and processes, the gas exiting the chamber is analyzed in an attempt to determine whether tungsten material remains on the inner surface of the enclosure. For example, if the gas exiting the chamber contains tungsten species, then it can be deduced that the removal process is not complete. In some other conventional systems and processes, sacrificial oxide-coated (for example, silicon dioxide (SiO₂)) test wafers are introduced into the plasma chamber for a predetermined duration of time during which the cleaning process is active. After the predetermined duration of cleaning, the wafer is removed and inspected. Because the gas, or components of the gas, used in the plasma cleaning process is generally selective to the metal or other conductive material (for example, tungsten) being removed, when the cleaning process is finished, the plasma begins to start etching the oxide on the wafer, which in some instances can be observed by the naked eye. In some conventional systems and processes, the cleaning process is repeated until visual observation indicates that all of the oxide on the wafer has been etched by the plasma. This typically requires many iterations of the plasma cleaning process (for example, tens or even a hundred or more), which can be time-consuming particularly given that the oxide test wafer is generally removed for inspection and replaced with a new test wafer after each iteration of the cleaning process. While removal, replacement and inspection of the oxide wafer may be automated, this oxide test wafer method remains an indirect measurement method and also can potentially introduce into the ICP system by-products and species that could be unwanted and detrimental for the core process itself.

The ability of the ICP system 100 to ignite, sustain or modulate a plasma in the reaction chamber 102 relies on the presence of a suitably-insulating barrier between the induction coil 106 and the plasma generated within the reaction chamber 102. One of the functions of the enclosure 104, other than being a container for the process gases, is providing this dielectric barrier. As described above, an inadvertent result of one or more processes performed by the ICP system 100 is the deposition and accumulation of metal or otherwise conductive thin films on an inside surface of the enclosure 104. As the accumulation of the conductive thin film on the inside surface of the enclosure 104 thickens and the distribution of the conductive thin film around the enclosure 104 increases, the ability of the ICP source system 100 to ignite, sustain or modulate a plasma in the reaction chamber 102 can be increasingly impeded or reduced, and the consistency of results from successive wafers being processed in the system can be compromised.

Various implementations can be used in conjunction with, or subsequent to the completion of, various deposition and treatment processes used to deposit a conductive metal, such as tungsten, in a feature as described above. Although various implementations disclosed herein are described with reference to applications involving the deposition, treatment or removal of tungsten, the implementations disclosed herein can generally be used in conjunction with applications involving other metals (for example, aluminum), metal alloys (e.g. WN) or other conductive materials.

FIG. 3 shows a flowchart illustrating an example process 300 for determining a measure of deposition of a conductive material on an inside surface of an enclosure of a reaction chamber of a plasma system. For example, the process 300 can be used to determine the deposition of a conductive material, such as tungsten, on the inside surface of the enclosure 104 of the ICP system 100 of FIG. 1. In one example implementation, the process 300 begins with the start of, and runs concurrently with, each plasma-facilitated intermediate treatment step performed after a deposition step as described above. For example, because plasma is already being generated for the treatment step, the same plasma can be concurrently used to facilitate the process 300. In other implementations, the process 300 can be used before, during or after other plasma-facilitated process steps that result, or can result, in the deposition of a conductive film on an inside surface of a plasma system. In some such implementations, a plasma is generated in the reaction chamber 102 specifically for use in determining the deposition of the conductive material on the enclosure 104 of the ICP system 100.

In block 302, the LFRF generator 108 supplies a first RF electrical signal to generate a plasma within the reaction chamber 102. Again, the RF electrical signal supplied by the LFRF generator 108 may be concurrently used to generate the plasma for a plasma-facilitated treatment process as described above. In some implementations, the LFRF generator 108 supplies the first RF electrical signal to the induction coil 106 at a voltage value in the range of approximately 200 volts (V) to approximately 8000 V. In one example implementation, the LFRF generator 108 provides the first RF electrical signal at approximately 2000 V. In some implementations, the LFRF generator 108 provides the first RF electrical signal to the induction coil 106 at a frequency in the range of approximately 200 kilo-Hertz (kHz) to 1000 kHz. In one example implementation that can be used in the treatment process described above (or the cleaning/removal process 400 described below), the LFRF generator provides the first RF electrical signal at approximately 400 kHz.

When the first RF electrical signal is supplied to the induction coil 106, the high voltage on the coils induces an electrical field in the reaction chamber 102 via capacitive coupling between the coils and the gas within the chamber that ignites the plasma. Because the plasma is itself conductive, the inductively-coupled electromagnetic field induces an electrical current in the plasma based on the first RF electrical signal supplied to the induction coil 106 that enhances the degree of ionization and the plasma density. Additionally, as a result of the impedance in the path or region between the induction coil 106 and the probe (for example, the pedestal 112), a voltage signal is provided to the probe as a function of the voltage developed on the coils (for example, such voltage can be in the range of tens to hundreds of volts). The impedance results from both the inductive coupling between the induction coil 106 and the plasma as well as the impedance of the dielectric enclosure 104. The voltage signal is conducted via the plasma to the probe (for example, the pedestal 112) where it is sensed as a second RF electrical signal. Because the second RF electrical signal received by the probe is based on the first RF electrical signal supplied to the induction coil 106, the second RF electrical signal will include a signal component having the same frequency as the frequency of the first RF electrical signal.

In block 304, a sensing device 228 begins sensing the second RF electrical signal received via the probe located within the reaction chamber 102. In various implementations, the probe can generally be any suitable metallic or otherwise conductive electrode or structure within the reaction chamber 102 that is electrically isolated from electrical ground of the enclosure 104. But as described above, in some implementations, the conductive top portion of the pedestal 112 functions as the probe. The large surface area of the top portion of the pedestal 112 can, in some instances, increase the effectiveness of various implementations described herein. In some other implementations, the ICP system 100 can include a specially-designed and located probe specifically for use in the process 300 and in the process 400 described below with reference to FIG. 4. The sensing device 228 can be located virtually anywhere within the ICP system 100 or otherwise integrated or in electrical communication with the probe. In some implementations, the sensing device 228 includes a sensing tool such as an oscilloscope to sense the second RF electrical signal received from the probe. In some other implementations, the sensing device 228 senses the second RF electrical signal with a more simplistic or specially-designed sensing tool capable of sensing electrical signals having frequencies within a frequency range in which the first RF electrical signal supplied by the LFRF generator is generated.

In some implementations, the sensing device 228 sends the sensed waveform of the second RF electrical signal received by the probe to a signal processing unit 230 that filters or otherwise processes the sensed waveform in block 306. Although described as a separate blocks, it should be appreciated that blocks 304 and 306 and other ones of the blocks described below can be performed concurrently and in substantially real time; that is, as the second RF electrical signal is received from the probe by the sensing device 228, the sensing device transmits or otherwise communicates the sensed waveform to the signal processing unit 230 for processing (it should also be appreciated that the process 300 can be performed on a continuous or periodic basis during and throughout each treatment step). In some implementations, the signal processing unit 230 includes software for performing one or more post-processing operations on the sensed waveform. In some implementations, the signal processing unit is included within the controller 224. In some such implementations, the signal processing unit 230 consists of one or more software modules including computer-readable instructions that are executed by one or more processors within the controller 224. In some other implementations, the signal processing unit 230 can be separate from the controller 224. In some such implementations, the signal processing unit 230 can be in communication with the controller 224. In some stand-alone implementations, the signal processing unit 230 can consist of hardware including, for example, capacitors, analog integrated circuits, microprocessors, or a combination of one or more of these or other physical components. In still other implementations, the signal processing unit 230 can include any suitable combination of hardware and software.

In some implementations, the signal processing unit 230 performs a Fourier Transform to transform the time-domain representation of the second RF electrical signal to a frequency-domain representation to allow removal of the components of the second RF electrical signal that do not have the same frequency as the first RF electrical signal (for example, 400 kHz) supplied by the LFRF generator 108 (for example, by frequency filtering). The processing unit can then use an inverse Fourier Transform to transform the frequency-domain filtered representation of the second RF electrical signal to a time-domain representation with the other frequency components removed. Additionally, in some implementations in which a third HFRF electrical signal (for example, a 13.56 mega-Hertz (MHz)) bias signal) is supplied to the pedestal 112 by the HFRF generator 116 (for example, to bias a wafer as described above), the signal processing unit 230 also can use the Fourier Transform method just described to remove the component of the second RF electrical signal that results from the third HFRF electrical signal.

In block 308, the signal processing unit 230 analyzes the filtered and processed second RF electrical signal to generate a metric based on an electrical characteristic of the signal that can be used to indicate when the deposition or distribution of the conductive layer on the inside of the enclosure 104 has reached a threshold value. In some other implementations, the signal processing unit 230 transmits the filtered and processed second RF electrical signal to the controller 224, which then generates the metric. In one example of a metric, the signal processing unit 230 (or the controller 224) can analyze the filtered and processed second RF electrical signal to determine the voltage amplitude of the component of the second RF electrical signal having the same frequency as the first RF electrical signal.

When the dielectric enclosure 104 is clean, the amplitude of the DC voltage of the second RF electrical signal is substantially constant (steady state). However, as a conductive film is deposited on the inside surface of the enclosure 104, the voltage signal developed on the induction coil 106 also is capacitively coupled with the conductive film. As the conductive film is increasingly deposited around the inside surface of the enclosure 104, and because the conductive film distributes the voltage signal throughout the film, more of the voltage signal developed on the induction coil 106 as a result of the first RF electrical signal is coupled into the film resulting in an increase in the amplitude of the second RF signal sensed at the probe. Additionally, as the distribution of the conductive film increases around the surface of the enclosure 104, particularly towards the probe, the distance the voltage signal must pass through the less conductive plasma in the reaction chamber 102 to the probe effectively decreases, which also can result in an increase in the amplitude of the second RF signal. Furthermore, as the thickness of the conductive film grows, the impedance of the film decreases. As the impedance of the film decreases, the voltage drop experienced by the voltage signal through the film decreases, and as a result, the amplitude of the second RF electrical signal measured at the probe increases. Thus, more generally, the amplitude of the second RF electrical signal varies as a function of the accumulation of conductive material on the inside surface of the dielectric enclosure 104 of the reaction chamber 102.

In some implementations, in block 310, the signal processing unit 230 (or the controller 224) determines whether the metric (for example, the voltage amplitude) of the second RF electrical signal has reached or exceeded a threshold value. For example, the threshold value can be a voltage value that indicates that the deposition of the conductive film on the enclosure has reached such a level as to warrant a cleaning operation. In various implementations, the threshold value can be theoretically or empirically determined. In some implementations, when the threshold value has been reached, the controller 224 outputs, in block 312, an indication to a user (for example via a display or other visual or auditory alert) indicating that the enclosure 104 should be cleaned or should be cleaned soon. In some other implementations, the controller 224 initiates a cleaning procedure in which the process wafer or other substrate is automatically removed and a cleaning process begins.

FIG. 4 shows a flowchart illustrating an example process 400 for determining when or whether a concurrently running cleaning process has completed the removal of an accumulation of conductive material on an inside surface of an enclosure of a reaction chamber of a plasma system. For example, the process 400 can be used to determine when a conductive material, such as tungsten, has been removed from the inside surface of the enclosure 104 of the ICP system 100 of FIG. 1. In one example implementation, the process 400 begins with the start of, and runs concurrently with, the cleaning process. In one specific example application, the ICP system 100 performs the cleaning process by forming and maintaining a plasma that breaks down NF₃ gas introduced into the reaction chamber into nitrogen and fluorine species (ions and radicals). The fluorine radicals are the active cleaning agents that etch (and remove) the tungsten deposited on the inside surface of the dielectric enclosure 104.

In block 402, the LFRF generator 108 supplies a first RF electrical signal to generate a plasma within the reaction chamber 102. Again, the RF electrical signal supplied by the LFRF generator 108 may be concurrently used to generate the plasma for the plasma-facilitated cleaning process. In some implementations, the LFRF generator 108 supplies the first RF electrical signal to the induction coil 106 at a voltage value in the range of approximately 200 volts (V) to approximately 8000 V. In one example implementation, the LFRF generator 108 provides the first RF electrical signal at approximately 2000 V. In some implementations, the LFRF generator 108 provides the first RF electrical signal to the induction coil 106 at a frequency in the range of approximately 200 kilo-Hertz (kHz) to 1000 kHz. In one example implementation that can be used in the cleaning/removal process, the LFRF generator 108 provides the first RF electrical signal at approximately 400 kHz.

Again, as described above, when the first RF electrical signal is supplied to the induction coil 106, the coils induce an electrical field in the reaction chamber 102 via inductive coupling between the coils and the gas within the chamber that ignites and sustains the plasma. In block 404, a sensing device 228 begins sensing a second RF electrical signal received via a probe located within the reaction chamber 102. As described above, in various implementations, the probe can generally be any suitable metallic or otherwise conductive electrode or structure within the reaction chamber 102 that is electrically isolated from ground and the walls of the enclosure 104. But as described above, in some implementations, the conductive top portion of the pedestal 112 functions as the probe.

In some implementations, the sensing device 228 sends the sensed waveform of the second RF electrical signal received by the probe to a signal processing unit 230 that filters or otherwise processes the sensed waveform in block 406. Although described as a separate blocks, it should be appreciated that blocks 404 and 406 and other ones of the blocks described below can be performed concurrently and in substantially real time; that is, as the second RF electrical signal is received from the probe by the sensing device 228, the sensing device transmits or otherwise communicates the sensed waveform to the signal processing unit 230 for processing (it should also be appreciated that the process 400 can be performed on a continuous or periodic basis during and throughout the concurrently running cleaning process).

In some implementations, the signal processing unit 230 performs a Fourier Transform to transform the time-domain representation of the second RF electrical signal to a frequency-domain representation to allow the removal of the components of the second RF electrical signal that do not have the same frequency as the first RF electrical signal (for example, 400 kHz) supplied by the LFRF generator 108 (for example, by frequency filtering). The processing unit can then use an inverse Fourier Transform to transform the filtered frequency-domain representation of the second RF electrical signal to a time-domain representation with the other frequency components removed.

In block 408, the signal processing unit 230 analyzes the filtered and processed second RF electrical signal to generate a metric based on an electrical characteristic of the signal that can be used to indicate when the conductive layer on the inside of the enclosure 104 has been removed. In some other implementations, the signal processing unit 230 transmits the filtered and processed second RF electrical signal to the controller 224, which then generates the metric. As described above, in one example of a metric, the signal processing unit 230 (or the controller 224) can analyze the filtered and processed second RF electrical signal to determine the voltage amplitude of second RF electrical signal having the same frequency as the first RF electrical signal.

As the accumulation of conductive material is removed during the cleaning process, the amplitude of the voltage amplitude of the second RF electrical signal will decrease. When the dielectric enclosure 104 is clean, the voltage amplitude of the second RF electrical signal is substantially constant. The steady state value would indicate that the removal of the conductive film is complete because there are no other changing variables that would cause the voltage amplitude to change. In some implementations, in block 410, the signal processing unit 230 (or the controller 224) determines whether the metric (for example, the voltage amplitude) of the second RF electrical signal has reached a steady-state value by examining values of the metric over a time period. In some implementations, when the value of the metric reaches a steady-state value, the controller 224 outputs, in block 412, an indication to a user (for example via a display or other visual or auditory alert) indicating that the conductive film on the enclosure 104 has been removed. In some other implementations, the controller 224 automatically terminates the cleaning process in block 412.

Although the foregoing implementations have been described in some detail for purposes of clarity of understanding, it will be apparent that certain changes and modifications may be practiced within the scope of the appended claims. It should be noted that there are other alternative ways of implementing the processes, systems and apparatus of the disclosed implementations. For example, in some other implementations, the apparatus, devices, methods and processes described herein can be implemented in a capacitively-coupled plasma (CCP) source system (for example, at a suitably low frequency) rather than an ICP source system as described above. Accordingly, the described implementations are to be considered as illustrative and not restrictive, and the implementations are not to be limited to the details given herein.

What is claimed is:

1. A system comprising:
a plasma system including:
a dielectric enclosure enclosing a portion of a reaction chamber;
a conductive coil extending along a perimeter of the enclosure; and
a generator for providing a first electrical signal to the coil to cause a plasma to be generated in the reaction chamber;
a probe located within the reaction chamber, the probe being electrically insulated from electrical ground at least while the first electrical signal is provided to the coil;
a sensing device for sensing a second electrical signal generated in the probe via the plasma while the first electrical signal is provided to the coil; and
one or more processing units for determining a metric based on the sensed second electrical signal, the metric indicating a measure of deposition or removal of a conductive material on an inside surface of the enclosure.

2. The system of claim 1, wherein the plasma system is an inductively-coupled plasma system.

3. The system of claim 1, wherein the first and the second electrical signals are radio frequency (RF) signals.

4. The system of claim 1, wherein one or more of the processing units include hardware or software for removing components of the sensed second electrical signal that have frequencies different than the frequency of the first electrical signal.

5. The system of claim 1, wherein the metric is a voltage amplitude of the second electric signal.

6. The system of claim 1, wherein:
the plasma is used to process a substrate, the process resulting in a deposition of the conductive material on the inside surface of the enclosure; and
one or more of the processing units are further for:
determining whether a value of the metric has reached a threshold value, the threshold value indicating that the deposition of the conductive material on the inside surface of the enclosure has reached a predetermined measure; and
when it is determined that the value of the metric has reached the threshold value, outputting an indication to clean the enclosure or initiating a cleaning process to clean the enclosure.

7. The system of claim 6, wherein the process is used to deposit or form a WFₓ species on or below a conductive surface of the substrate.

8. The system of claim 6, wherein the process is used to deposit a conductive material on the substrate.

9. The system of claim 1, wherein:
the plasma is used in a cleaning process to remove conductive material previously deposited on the inside surface of the enclosure; and
one or more of the processing units are further for:
determining whether a value of the metric over a time period has become substantially steady state, the steady state indicating that the removal of the conductive material on the inside surface of the enclosure has been substantially completed; and
when it is determined that the value of the metric has become substantially steady state, outputting an indication that the cleaning process is complete or initiating an end to the cleaning process.

10. The system of claim 1, wherein the system further includes a conductive platform for supporting the substrate in the reaction chamber.

11. The system of claim 10, wherein the platform functions as or includes the probe.

12. A method comprising:
supplying, by a first generator, a first electrical signal to a coil of a plasma system to cause a plasma to be generated in a reaction chamber of the plasma system, the reaction chamber being at least partially enclosed by a dielectric enclosure;
sensing, by a sensing device, an electrical characteristic of a second electrical signal generated in a probe via the plasma while the first electrical signal is provided to the coil, the probe being arranged within the reaction chamber; and
determining a metric based on the electrical characteristic, the metric indicating a measure of deposition or removal of a conductive material on an inside surface of the enclosure.

13. The method of claim 12, wherein the plasma system is an inductively-coupled plasma system.

14. The method of claim 12, wherein the first and the second electrical signals are radio frequency (RF) signals.

15. The method of claim 12, further including removing, from the sensed second electrical signal, components of the sensed second electrical signal that have frequencies different than the frequency of the first electrical signal.

16. The method of claim 12, wherein the metric is a voltage amplitude of the second electric signal.

17. The method of claim 12, wherein:
the plasma is used to process a substrate, the process resulting in a deposition of the conductive material on the inside surface of the enclosure; and
the method further includes:
determining whether a value of the metric has reached a threshold value, the threshold value indicating that the deposition of the conductive material on the inside surface of the enclosure has reached a predetermined measure; and
when it is determined that the value of the metric has reached the threshold value, outputting an indication to clean the enclosure or initiating a cleaning process to clean the enclosure.

18. The method of claim 17, wherein the process is used to deposit or form a WFₓ species on or below a conductive surface of the substrate.

19. The method of claim 17, wherein the process is used to deposit a conductive material on the substrate.

20. The method of claim 12, wherein:
the plasma is used in a cleaning process used to remove conductive material deposited on the inside surface of the enclosure; and
the method further includes:
determining whether a value of the metric over a time period has become substantially steady state, the steady state indicating that the removal of the conductive material on the inside surface of the enclosure has been substantially completed; and
when it is determined that the value of the metric has become substantially steady state, outputting an indication that the cleaning process is complete or initiating an end to the cleaning process.
